(19) United States
(12) Patent Application Publication
(10) Pub. No.: US 2009/0195981 A1
(43) Pub. Date: Aug. 6, 2009

(54) Heat dissipating air flow channel structure of electronic device

(75) Inventor: Chun-Ju Lin, Taipei County (TW)

Correspondence Address: BACON & THOMAS, PLLC, 625 SLATERS LANE, FOURTH FLOOR, ALEXANDRIA, VA, 22314-1176, US

(73) Assignee: TEK-CHAIN TECHNOLOGY CO., LTD., Taoyuan City (TW)

(21) Appl. No.: 12/010,912

(22) Filed: Jan. 31, 2008

(51) Int. Cl. H05K 7/20; G06F 1/20; H05K 5/00

(52) U.S. Cl. 361/695

(57) ABSTRACT

The present invention discloses a heat dissipating air flow channel structure of an electronic device, and the structure is mainly used in an electronic device having a fan. The electronic device includes a casing, a fan installed in the casing, a body disposed on an external side of the casing and parallel to the axial direction of the fan, and air guide holes disposed on the body and having air guide hoods for guiding the air of an air flow channel, so that the hot air produced by the electronic device is guided in a specific direction along the air guide hoods and will not sucked back into the electronic device again, so as to improve the heat dissipating effect.

### BACKGROUND OF THE INVENTION

1. Field of the Invention

The present invention relates to a heat dissipating air flow channel structure of an electronic device, and more particularly to an electronic device having a fan, such that after hot air produced in the electronic device is discharged to the outside, the hot air will not be sucked back into the electronic device by the fan again, so as to improve the heat dissipating effect.

2. Description of the Related Art

In general, an electronic device (such as a power supply device) that will generate heat of a high temperature usually installs a fan to dissipate the heat. Referring to FIG. 1, the power supply device comprises a metal casing 110 and a fan 120, and the fan 120 is fixed into the casing 110. The casing 110 has an opening 121 disposed on a surface opposite to the fan 120, and a plurality of heat dissipating holes 122 disposed at an edge corresponding to the fan 120, so that when the fan 120 is operated, the fan 120 forms an air inlet area and air outlet area on both ends of the fan respectively and along the axial direction of the fan (i.e. the fan is in a direction facing the casing opening) and sucks external cold air from the opening 121 and the heat dissipating holes 122 proximate to the opening 121 into the casing 110. The hot air is discharged from the heat dissipating holes 122 on middle and lower layers of the casing 110 to the outside. However, a portion of the hot air discharged from the heat dissipating holes 122 at the middle and lower layers of the casing 110 will be sucked back into the heat dissipating holes 122 proximate to the opening 121 due to a large external pressure, and thus adversely affecting the heat dissipating effect. Obviously, the prior art requires further improvements.

### SUMMARY OF THE INVENTION

In view of the shortcomings of the prior art, the inventor of the present invention based on years of experience in the related industry to conduct extensive researches and experiments, and finally developed a heat dissipating air flow channel structure in accordance with the present invention to overcome the shortcomings of the prior art.

Therefore, it is a primary objective of the present invention to provide an electronic device having a heat dissipating air flow channel structure capable of improving the absorption of external cold air.

A second objective of the present invention is to provide an electronic device that guides hot air produced by an electronic device to the outside in a specific direction, so that the hot air will not be sucked back into the electronic device again, so as to improve the heat dissipating effect.

To achieve the foregoing objectives, the present invention provides a heat dissipating air flow channel structure that is applied to an electronic device having a fan, and the structure comprises a body disposed on an external side of a casing of the electronic device, and the body and the casing are integrally or separately formed. The body further includes a plurality of air guide holes disposed thereon for guiding air through the air guide hood having an air flow channel.

The body further includes at least one partition, for separating the body into at least two air guide areas, and each air guide area includes at least one air guide hole, so that air can be sucked or discharged through the partitions effectively. After the hot air produced by the electronic device is discharged to the outside, the hot air will not be sucked back into the electronic device again, so as to improve the heat dissipating effect.

To make it easier for our examiner to understand the object, shape, structure, apparatus, characteristics and performance of the invention, we use preferred embodiments together with the attached drawings for the detailed description of the invention.

### BRIEF DESCRIPTION OF THE DRAWINGS

FIG. 1 shows a schematic view of a conventional device;

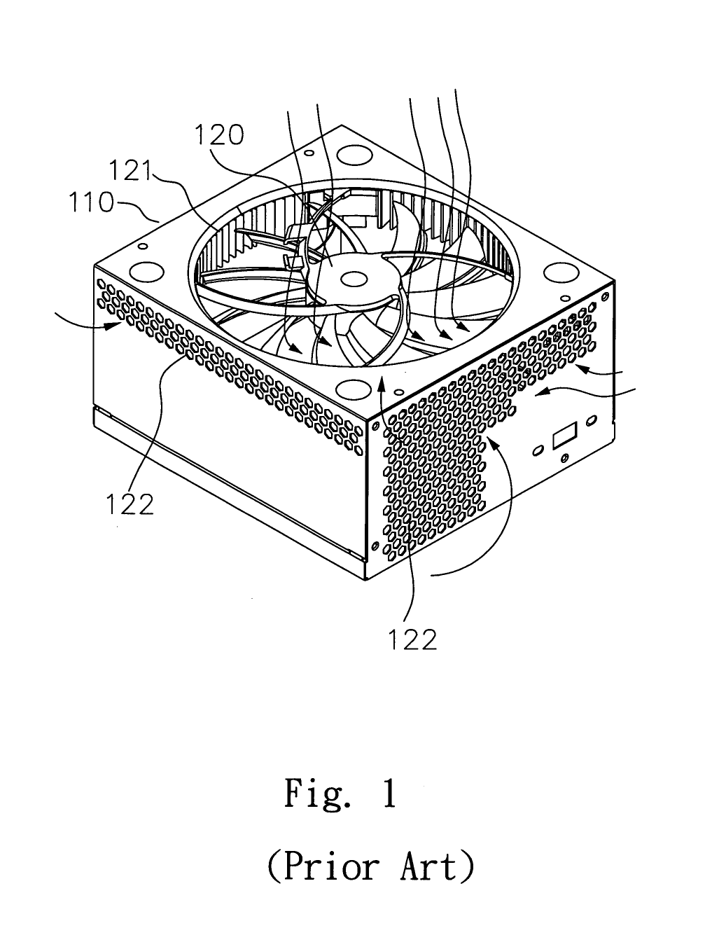

FIG. 2 shows a perspective view of a heat dissipating air flow channel structure applied to a power supply device in accordance with a first preferred embodiment of the present invention;

FIG. 3 shows a perspective view of a heat dissipating air flow channel structure applied to a power supply device in accordance with a second preferred embodiment of the present invention;

FIG. 4 shows a perspective view of a heat dissipating air flow channel structure applied to a power supply device in accordance with a third preferred embodiment of the present invention;

FIG. 5 shows a perspective view of a heat dissipating air flow channel structure applied to a power supply device in accordance with a fourth preferred embodiment of the present invention;

FIG. 6 shows a perspective view of a heat dissipating air flow channel structure applied to a computer in accordance with a first preferred embodiment of the present invention; and

FIG. 7 shows a perspective view of a heat dissipating air flow channel structure applied to a computer in accordance with a second preferred embodiment of the present invention.

### DETAILED DESCRIPTION OF THE PREFERRED EMBODIMENTS

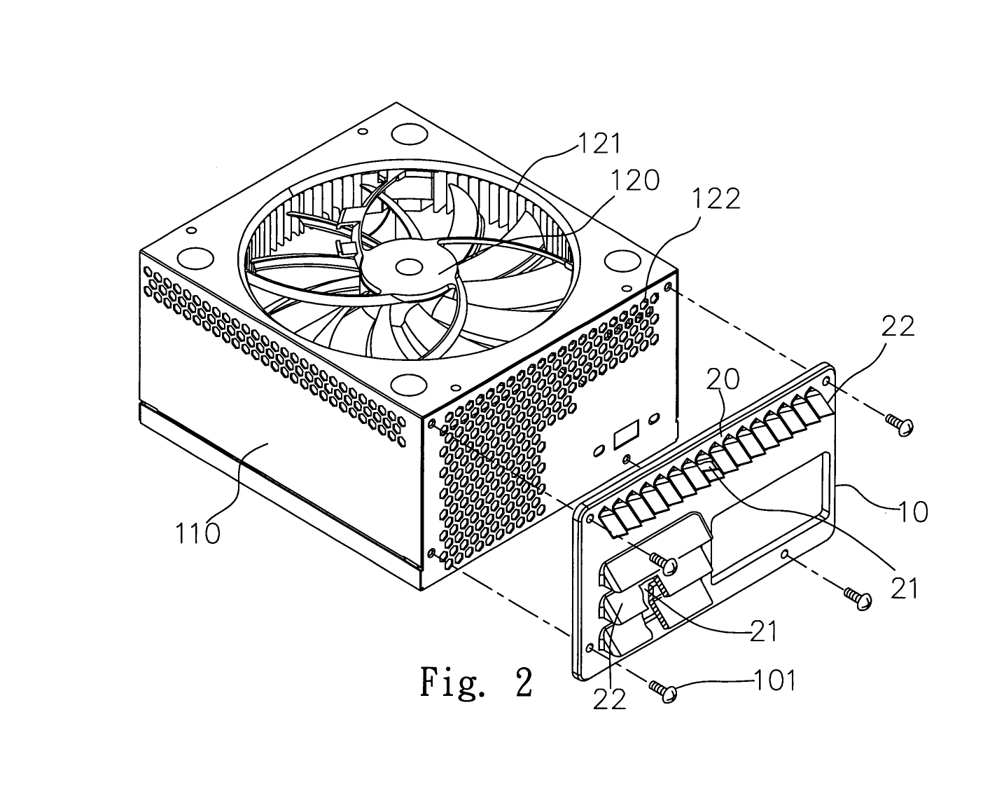

The present invention is applied to an electronic device (which is a power supply device in this embodiment, but those skilled in the art can apply the invention to other electronic products) having a fan. In FIG. 2, the electronic device comprises a casing 110, a fan 120 (which can be a bare fan without a frame or a fan with a frame having air inlet areas disposed on the lateral side of the frame) installed in the casing 110, an opening 121 disposed on the casing 110 and opposite to the fan 120, and a plurality of heat dissipating holes 122 disposed on the casing 110 and opposite to an edge of the fan. When the fan 120 is operated, the fan 120 forms an air inlet area and an air outlet area on both ends of the fan respectively and along the axial direction of the fan (i.e. the fan is installed in a direction facing the opening of the casing), so that the fan 120 will suck external cold air from the air inlet area or the edges of the frame of the fan 120 into the casing 110.

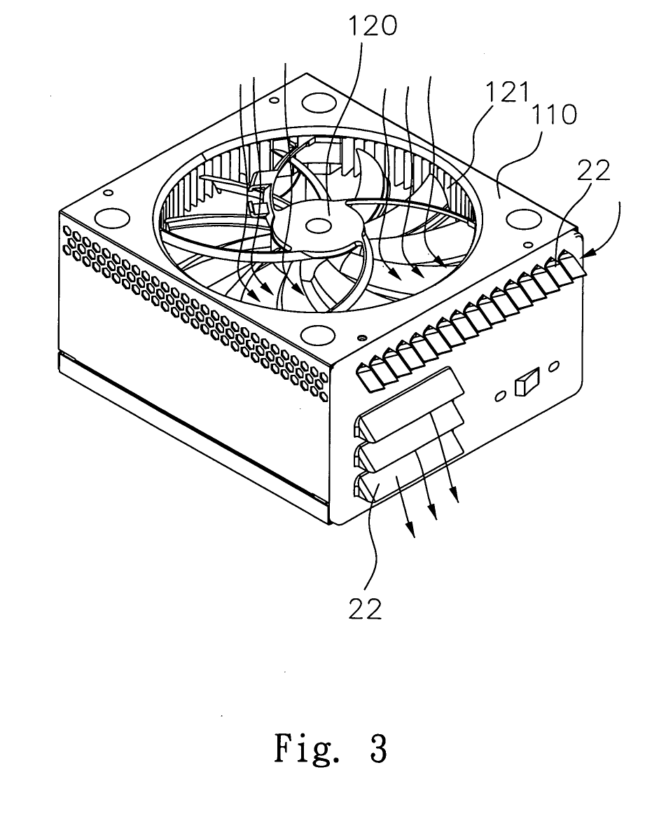

Referring to FIGS. 2 and 3 for a second preferred embodiment of the present invention, the invention comprises a body 10 fixed on an external side of the casing 110 of the electronic device and parallel to the axial direction of the fan 120, and the body 10 can be mounted onto a lateral surface of the casing 110 by a screw 101 (as shown in FIG. 2). The body 10 is a rectangular plate in this embodiment, or integrally formed with a lateral surface of the casing 110 (as shown in FIG. 3), and the body 10 includes a plurality of air guide holes 21 interconnected with air flow channels of the fan 120, and the air guide holes 21 have air guide hoods 22 for guiding the air flow in the air flow channels, and the air guide hoods 22 can be aligned in the same guiding direction or in different guiding directions, so that the electronic device can be installed in a corresponding position to select an appropriate air flow guiding direction. After the hot air is guided in a specific direction by the air guide hoods and separated from the cold air, the hot air will not be sucked back into the electronic device again, so as to improve the heat dissipating effect.

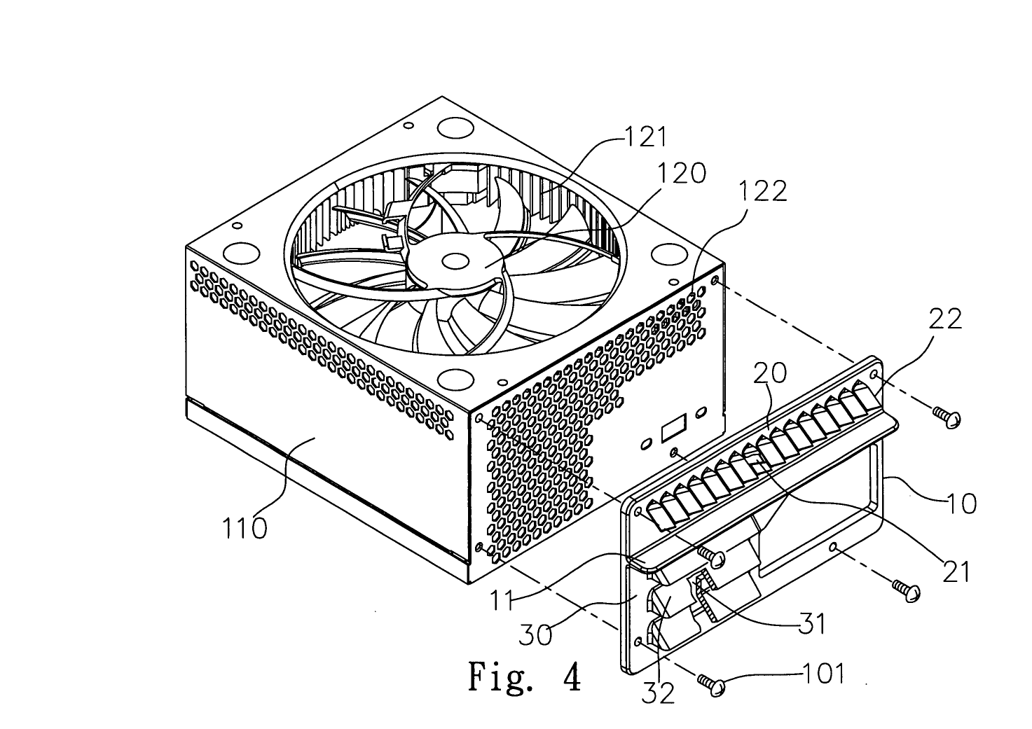

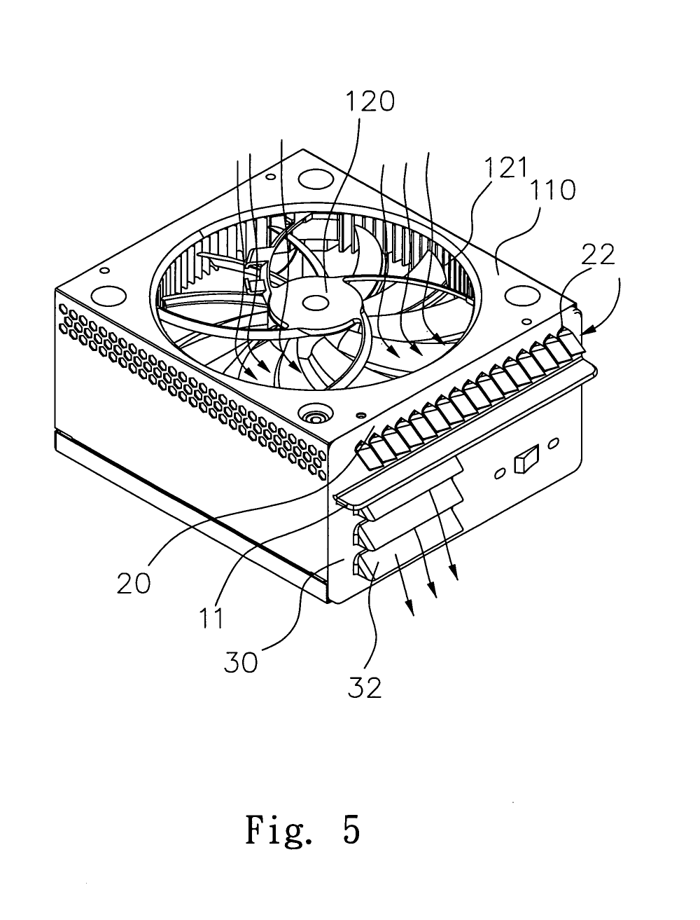

Referring to FIGS. 4 and 5 for the third and fourth preferred embodiments of the invention respectively, the body is fixed onto an external side of the casing 110 of the electronic device and parallel to the axial direction of the fan 120, and secured onto a lateral surface of the casing 110 by a screw 101 (as shown in FIG. 4). In this embodiment, the body 10 is a rectangular plate, or integrally formed with a lateral surface of the casing 110 (as shown in FIG. 5). The body 10 further includes at least one partition 11 extended and protruded perpendicularly from the axial direction of the fan 120 for separating the body 10 into at least first and second air guide areas 20, 30, and the first and second air guide areas 20, 30 have at least one air guide hole 21, 31 each, wherein the air guide hole 21 of the first air guide area 20 is provided for guiding external cold air into the fan 120. An air guide hood 22 is installed on the air guide hole 21, and an opening of the air guide hood 22 can be designed in any direction (which is obliquely upward in this embodiment). The air guide hole 31 of the second air guide area 30 is provided for discharging hot air from the electronic device to the outside, and the air guide hole 31 includes an air guide hood 32 whose opening can be designed towards any direction (which is obliquely upward in this embodiment), so that when the body 10 is fixed onto an external side of the casing 110 and the fan 120 is operated, external cold air is guided by the air guide hole 21 and the air guide hood 22 disposed on the first air guide area 20 to expedite its air flow from the air guide hole 21 of the first air guide area 20 of the fan 120 into the fan 120, and then guided by the air guide hood 32 proximate to the air guide hole 31 of the second air guide area 30 of the electronic device. After the hot air is discharged to the outside, the hot air will not be sucked back into the electronic device again, so as to improve the heat dissipating effect.

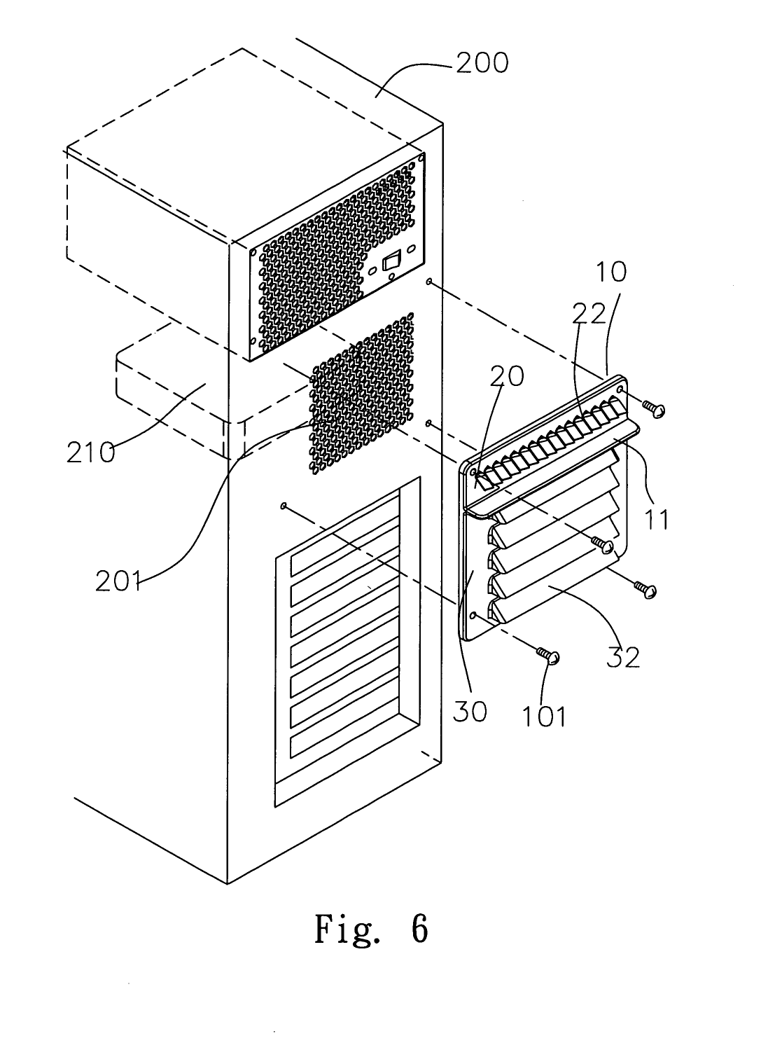

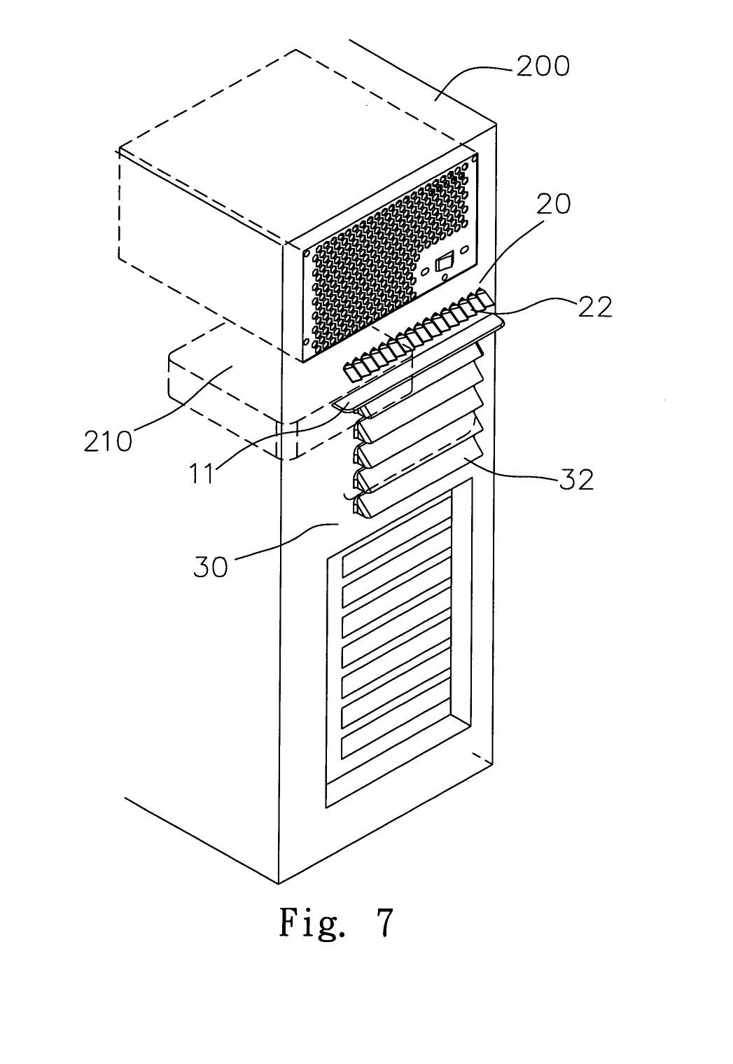

Referring to FIGS. 6 and 7 for an embodiment applied in a computer, the computer includes a casing 200, a fan 210 fixed onto the casing 200, a plurality of heat dissipating holes 201 disposed on the casing 200 and opposite to a lateral side of the fan 210, and a body 10 mounted onto the heat dissipating holes 201 and parallel to the axial direction of the fan and secured onto a lateral surface of the casing 200 by a screw 101 (as shown in FIG. 6), wherein the body 10 is a rectangular plate, or integrally formed with the casing 200 in this embodiment (as shown in FIG. 7).

The body 10 further includes at least one partition 11 extended and protruded perpendicularly from the axial direction of the fan 210 (wherein this embodiment adopts a partition, but those skilled in the art may adopt any other equivalent design as needed). The partition 11 separates the body 10 into at least two areas, and the body 10 separates the partition 11 into a first and second air guide areas 20, 30, and the first and second air guide areas 20, 30 have at least one air guide hole 21, 31 each, wherein the air guide hole 21 of the first air guide area 20 is provided for guiding external cold air into the fan 210, and the air guide hole 21 has an air guide hood 22 whose opening can be designed in any direction (which is obliquely upward in this embodiment). The air guide hole 31 of the second air guide area 30 is provided for guiding hot air in the casing 200 to the outside, and the air guide hole 31 has an air guide hood 32 whose opening can be designed in any direction (which is obliquely downward in this embodiment), such that the body 10 and the casing 200 can be engaged with each other. When the fan 210 in the electronic device is operated, external cold air can be guided from the air guide hole 21 and the air guide hood 22 of the first air guide area 20 and expedited from the air guide hole 21 proximate to the first air guide area 20 of the fan 210 into the fan 210, and then guided from the air guide hood 32 proximate to the air guide hole 31 of the second air guide area 30 of the electronic device. After the hot air is discharged to the outside, the hot air will not be sucked back into the electronic device again, so as to improve the heat dissipating effect.

In summation of the description above, the present invention improves over the prior art and complies with the requirements of patent application, and is thus duly filed for patent application. While the invention has been described by means of specific embodiments, numerous modifications and variations could be made thereto by those skilled in the art without departing from the scope and spirit of the invention set forth in the claims.

What is claimed is:

1. A heat dissipating air flow channel structure of an electronic device, applied to a casing of an electronic device having a fan, and the structure comprising:
a body, fixed on an external side of said casing of said electronic device, and parallel to an axial direction of said fan;
a plurality of air guide holes, disposed on said body, and interconnected with an air flow channel of said fan in said casing;
a plurality of air guide hoods, installed on said air guide holes, for guiding an air flow to a specific direction to improve a heat dissipating effect.

2. The heat dissipating air flow channel structure of an electronic device according to claim 1, wherein said air flow channels of said air guide hood are aligned in the same direction.

3. The heat dissipating air flow channel structure of an electronic device according to claim 1, wherein said air flow channels of said air guide hood are aligned in different directions.

4. The heat dissipating air flow channel structure of an electronic device according to claim 1, wherein said body and said casing are separate members.

5. The heat dissipating air flow channel structure of an electronic device according to claim 4, wherein said body is mounted onto an external side of said casing by a screw.

6. The heat dissipating air flow channel structure of an electronic device according to claim 1, wherein said body and said casing are integrally formed.

7. The heat dissipating air flow channel structure of an electronic device according to claim 1, wherein said electronic device is a power supply device.

8. The heat dissipating air flow channel structure of an electronic device according to claim 1, wherein said electronic device is a computer.

9. The heat dissipating air flow channel structure of an electronic device according to claim 1, wherein said body further comprises at least one partition, and said partition is fixed on said body, extended horizontally and protruded to the outside, such that said partition separates a plurality of air guide areas.

10. The heat dissipating air flow channel structure of an electronic device according to claim 9, wherein said partition comes with a quantity of one, for separating said air guide area into first and second air guide areas by said partition.

11. The heat dissipating air flow channel structure of an electronic device according to claim 9, wherein said partition comes with a quantity of at least two, for separating said air guide area into a plurality of layers of air guide areas by said partitions.

12. The heat dissipating air flow channel structure of an electronic device according to claim 10, wherein said air flow channels of said air guide hoods of said first and second air guide areas are aligned in the same direction.

13. The heat dissipating air flow channel structure of an electronic device according to claim 10, wherein said air flow channels of said air guide hoods of said first and second air guide areas are aligned in different directions.

14. The heat dissipating air flow channel structure of an electronic device according to claim 9, wherein said body and said casing are separate members.

15. The heat dissipating air flow channel structure of an electronic device according to claim 14, wherein said body is mounted on an external side of said casing by a screw.

16. The heat dissipating air flow channel structure of an electronic device according to claim 9, wherein said body and said electronic device are integrally formed.

17. The heat dissipating air flow channel structure of an electronic device according to claim 9, wherein said electronic device is a power supply device.

18. The heat dissipating air flow channel structure of an electronic device according to claim 9, wherein said electronic device is a computer.
